(19) United States
(12) Patent Application Publication
(10) Pub. No.: US 2025/0361354 A1
(43) Pub. Date: Nov. 27, 2025

(54) RESIN COMPOSITION FOR ENCAPSULATING ELECTRONIC DEVICE AND ELECTRONIC DEVICE MANUFACTURED USING THE SAME

(71) Applicant: DONGWOO FINE-CHEM CO., LTD., Jeollabuk-do (KR)

(72) Inventors: YU MI AHN, Jeollabuk-do (KR); MIN SEOK KI, Jeollabuk-do (KR); SU SEONG KIM, Jeollabuk-do (KR); SEONG HWAN PARK, Jeollabuk-do (KR)

(21) Appl. No.: 19/211,447

(22) Filed: May 19, 2025

(30) Foreign Application Priority Data
May 22, 2024 (KR) 10-2024-0066213

(51) Int. Cl. C08G 59/22; C08G 59/24; C08G 59/40; C08G 59/68; C08K 3/22; C08K 5/01; C08K 5/5425; C08K 5/544

(52) U.S. Cl. CPC C08G 59/226; C08G 59/245; C08G 59/68; C08K 3/22; C08K 5/01; C08K 5/5425; C08K 5/544; C08G 59/40; C08K 2003/2227

(57) ABSTRACT

A resin composition for encapsulating an electronic device according to an embodiment includes an epoxy compound, an inorganic filler, a (meth)acrylamide compound containing an alkoxysilyl group, and a release agent. The release agent may include a wax having an average acid value of 15 mgKOH/g to 200 mgKOH/g. An electronic device may include a sealant formed of the resin composition.

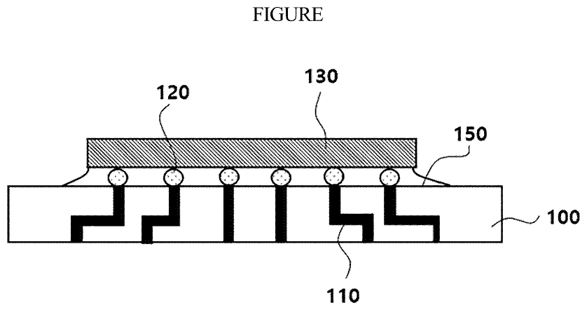

### CROSS REFERENCE TO RELATED APPLICATION AND CLAIM OF PRIORITY

This application claims the benefit under 35 USC § 119 of Korean Patent Application No. 10-2024-0066213 filed on May 22, 2024 in the Korean Intellectual Property Office, the entire disclosure of which is incorporated herein by reference for all purposes.

### BACKGROUND

### 1. Field of the Invention

The present invention relates to a resin composition for encapsulating an electronic device and an electronic device manufactured using the same. More specifically, the present invention relates to a resin composition for encapsulating an electronic device, which includes an epoxy compound and an additive, and an electronic device manufactured using the resin composition.

### 2. Description of the Related Art

An integrated circuit (IC) chip including a semiconductor device is surface-mounted on a circuit board, for example, through a bump, solder, or ball grid array (BGA). The semiconductor device may be encapsulated or packaged on the circuit board using an epoxy molding compound (EMC)-based resin.

Recently, as the integration density of the semiconductor device increases and its size decreases, there is a need to apply an encapsulation resin composition having improved moldability and curing characteristics.

For example, after mounting an IC chip on a BGA substrate, a gap between the IC chip and the BGA substrate may be filled with the EMC composition to fix the IC chip.

The smaller the gap, the more necessary it is to use an EMC composition having a sufficient flow length. In addition, heat dissipation characteristics, which allows sufficient dissipation of heat generated during operation of the semiconductor device to the outside, may also be required for the EMC composition.

In addition, the EMC composition needs to provide sufficient thermal stability to withstand the heat generated from the semiconductor device and to ensure stable chip fixation characteristics.

### SUMMARY

An object of the present invention is to provide a resin composition for encapsulating an electronic device that exhibits improved moldability.

Another object of the present invention is to provide an electronic device which is manufactured using the resin composition for encapsulating an electronic device.

To achieve the above objects, the following technical solutions are adopted in the present invention.
1. A resin composition for encapsulating an electronic device including: an epoxy compound; an inorganic filler; a (meth)acrylamide compound including an alkoxysilyl group; and a release agent including a wax having an average acid value of 15 mgKOH/g to 200 mgKOH/g.
2. The resin composition for encapsulating an electronic device according to the above 1, wherein the alkoxysilyl group includes a trialkoxysilyl group.
3. The resin composition for encapsulating an electronic device according to the above 1, wherein the (meth)acrylamide compound is represented by Formula 1 below:

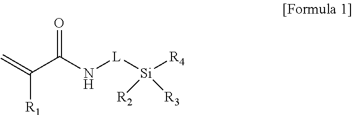

(in Formula 1 above, R₁ is hydrogen or a methyl group, R₂ to R₄ are each independently an alkoxy group having 1 to 5 carbon atoms, and L is an alkylene group having 1 to 10 carbon atoms).
4. The resin composition for encapsulating an electronic device according to the above 1, wherein the (meth)acrylamide compound includes N-(3-(trimethoxysilyl)propyl)methacrylamide.
5. The resin composition for encapsulating an electronic device according to the above 1, wherein a content of the (meth)acrylamide compound is 0.05% by weight to 1.5% by weight based on a total weight of the composition.
6. The resin composition for encapsulating an electronic device according to the above 1, wherein the wax has an average acid value of 17 mgKOH/g to 150 mgKOH/g.
7. The resin composition for encapsulating an electronic device according to the above 1, wherein the wax includes at least one selected from the group consisting of an ester wax, a paraffin wax, an amide wax, and an olefin wax.
8. The resin composition for encapsulating an electronic device according to the above 7, wherein the ester wax includes an ester wax derived from a carboxylic acid having an alkyl group with 20 to 50 carbon atoms.
9. The resin composition for encapsulating an electronic device according to the above 1, wherein a content of the release agent is 0.05% by weight to 1.5% by weight based on the total weight of the composition.
10. The resin composition for encapsulating an electronic device according to the above 1, wherein a ratio of the content of the release agent to the content of the (meth)acrylamide compound, based on the total weight of the composition, is 0.7 to 2 by weight.
11. The resin composition for encapsulating an electronic device according to the above 1, wherein the epoxy compound includes a biphenyl-based epoxy compound and a biphenyl-aralkyl-based epoxy compound.
12. The resin composition for encapsulating an electronic device according to the above 11, wherein the biphenyl-based epoxy compound is represented by Formula 2 below:

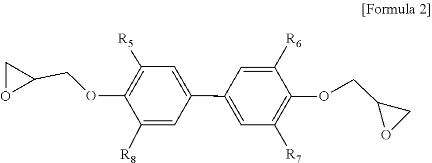

(in Formula 2 above, R₅, R₆, R₇ and R₈ are each independently hydrogen or an alkyl group having 1 to 5 carbon atoms.)
13. The resin composition for encapsulating an electronic device according to the above 11, wherein the biphenyl-aralkyl epoxy compound is represented by Formula 3 below:

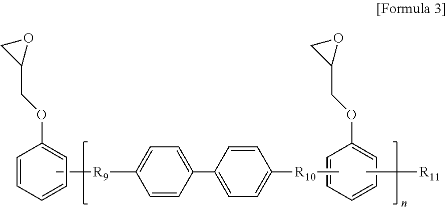

(in Formula 3 above, R₉ and R₁₀ are each an alkylene group having 1 to 5 carbon atoms, R₁₁ is hydrogen or an alkyl group having 1 to 5 carbon atoms, and n is an integer of 1 to 10).
14. The resin composition for encapsulating an electronic device according to the above 11, wherein a weight ratio of the biphenyl-based epoxy compound to the biphenyl-aralkyl epoxy compound in the epoxy compound is greater than 1 and 8 or less.
15. The resin composition for encapsulating an electronic device according to the above 1, further including an additive which includes at least one selected from the group consisting of a catalyst, a coupling agent, a colorant, and a curing agent.
16. An electronic device including a sealant formed of the resin composition for encapsulating an electronic device according to the above 1.
17. The electronic device according to the above 16, further including a circuit board and a semiconductor chip mounted on the circuit board, wherein the sealant fills a space between the circuit board and the semiconductor chip.

The resin composition for encapsulating an electronic device according to the embodiments of the present invention may exhibit improved moldability due to its high flowability. Accordingly, the flow length of the composition may increase. In addition, the resin composition for encapsulating an electronic device according to exemplary embodiments of the present invention may have high flexural strength and improved mechanical stability.

The resin composition for encapsulating an electronic device may be used as an encapsulation resin for a highly integrated semiconductor package, thereby improving the mounting reliability of integrated circuit chips having fine dimensions.

### BRIEF DESCRIPTION OF THE DRAWINGS

The above and other objects, features and other advantages of the present invention will be more clearly understood from the following detailed description taken in conjunction with the accompanying drawing, in which:

FIGURE is a schematic cross-sectional view illustrating a semiconductor package in which a resin composition for encapsulating an electronic device according to exemplary embodiments is used.

### DETAILED DESCRIPTION OF THE INVENTION

According to embodiments of the present invention, there is provided a resin composition for encapsulating an electronic device, which includes an epoxy compound, an inorganic filler, a (meth)acrylamide compound, and a release agent. In addition, according to embodiments of the present invention, there is provided an electronic device in which the resin composition for encapsulating an electronic device is used.

### Resin composition for Encapsulating an Electronic Device

The resin composition for encapsulating an electronic device according to exemplary embodiments (hereinafter, may be abbreviated as a resin composition) may include an epoxy compound, an inorganic filler, a (meth)acrylamide compound, and a release agent. In some embodiments, the resin composition may further include an additive.

The term “resin composition” as used herein may encompass both cases where a resin is directly included in the composition and where the resin is formed by curing the composition. (meth)acrylamide compound

The composition may include a (meth)acrylamide compound. The (meth)acrylamide compound may include an alkoxysilyl group. Molding characteristics and mechanical properties of the composition may be effectively implemented by the (meth)acrylamide compound.

The term “alkoxysilyl group” as used herein may refer to a functional group in which at least one epoxy group is bonded to a silicon (silane) atom, and which can be bonded to another element through the silicon atom.

The (meth)acrylamide compound may include a (meth)acrylamide group. The term “(meth)acrylamide group” as used herein may refer to a structure in which a (meth)acryl group and an amide group are bonded by sharing a carbonyl group.

The (meth)acrylamide compound includes both an alkoxysilyl group and a (meth)acrylamide group, which enables the thermal properties of the inorganic filler to be maintained. Therefore, the flexural strength and flow length of the resin composition may be improved while maintaining thermal stability of the resin composition.

For example, when a compound including only an alkoxysilyl group is used, the bonding stability with the epoxy compound may be reduced, thereby leading to a decrease in the flexural strength.

For example, when the (meth)acrylamide compound does not include an alkoxysilyl group, it may not bond with the inorganic filler, and thus the surface of the inorganic filler may not be sufficiently modified. Accordingly, the bonding between the epoxy compound and the inorganic filler may be weakened, thereby leading to a decrease in the mechanical properties of the composition.

The (meth)acrylamide group and the alkoxysilyl group may be linked by a hydrocarbon chain having 1 to 10 carbon atoms, or by a hydrocarbon chain having 1 to 10 carbon atoms and including one or more —O—, —S—, —NH— groups in the chain.

According to exemplary embodiments, the alkoxysilyl group may include a trialkoxysilyl group. The trialkoxysilyl group, in which three alkoxy groups are bonded to a silicon atom, may have three alkyl groups of different lengths or may have three alkyl groups of the same length.

According to exemplary embodiments, the (meth)acrylamide compound may be represented by Formula 1 below.

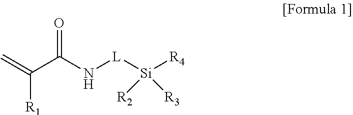

In Formula 1 above, R₁ may be hydrogen or a methyl group. When R₁ is hydrogen, the compound may be an acrylamide compound, and when R₁ is a methyl group, the compound may be a methacrylamide compound.

In Formula 1 above, R₂ to R₄ may each independently be an alkoxy group having 1 to 5 carbon atoms. For example, R₂ to R₄ may each independently be a methoxy group, an ethoxy group or a propoxy group.

In Formula 1 above, L may be an alkylene group having 1 to 10 carbon atoms. For example, L may be a methylene group, an ethylene group, a propylene group, a butylene group or a pentylene group.

For example, the (meth)acrylamide compound may include N-(3-(trimethoxysilyl)propyl)methacrylamide.

According to exemplary embodiments, the (meth)acrylamide compound may be added separately from the inorganic filler to be included in the resin composition. Alternatively, the (meth)acrylamide compound may be used for the surface treatment of the inorganic filler to be included in the resin composition in a state of being coated on the surface of the inorganic filler. The interfacial energy on the surface of the surface-treated inorganic filler may be adjusted, thereby promoting stable bonding between the inorganic filler and the epoxy compound. As a result, the flowability of the resin composition may be ensured, and the flexural strength may be improved. Accordingly, the mechanical properties of the resin composition may be improved.

According to exemplary embodiments, a content of the (meth)acrylamide compound may be 0.05% by weight (“wt %”) to 1.5 wt % based on the total weight of the composition. According to some embodiments, the content of the (meth) acrylamide compound may be 0.05 wt % to 1.2 wt %, 0.1 wt % to 1 wt %, or 0.2 wt % to 0.5 wt % based on the total weight of the composition.

Within the above range, the thermal expansion coefficient of the resin composition may be adjusted to ensure thermal stability. In addition, the flexural strength of the resin composition may be adjusted to ensure mechanical stability.

### Release Agent

The composition may include a release agent. The release agent may include a wax. The release agent may improve the flowability of the composition.

In exemplary embodiments, the wax may have an average acid value of 15 mgKOH/g to 200 mgKOH/g. In some embodiments, the wax may have an average acid value of 17 mgKOH/g to 180 mgKOH/g or 17.5 mgKOH/g to 150 mgKOH/g.

When the composition includes the (meth)acrylamide compound, the flexural strength may increase, whereas the flow length may decrease. The composition of the present disclosure may include a wax having an average acid value of 15 mgKOH/g to 200 mgKOH/g, thereby preventing a decrease in the flowability of the composition and increasing the flow length.

If the average acid value of the wax is less than 15 mgKOH/g, the flowability of the composition may not be improved, and may even decrease the flexural strength.

If the average acid value of the wax exceeds 200 mgKOH/g, there may be a problem with moisture absorption.

In exemplary embodiments, the wax may be an ester wax, a paraffin wax, an amide wax, an olefin wax or the like. For example, the wax may be an ester wax, and the ester wax may include an ester wax derived from a fatty acid (a carboxylic acid having a long-chain alkyl group).

In exemplary embodiments, the ester wax may include an ester wax derived from a carboxylic acid having an alkyl group with 20 to 50 carbon atoms. For example, the ester wax may include an ester wax derived from a fatty acid such as stearic acid or montanic acid.

In exemplary embodiments, a content of the release agent may be 0.05 wt % to 1.5 wt % based on the total weight of the composition. In some embodiments, the content of the release agent may be 0.05 wt % to 1.2 wt %, 0.1 wt % to 1 wt %, or 0.2 wt % to 0.5 wt % based on the total weight of the composition.

Within the above range, the flow length of the composition may be increased and the flowability may be improved.

In exemplary embodiments, a ratio of the content of the release agent to the content of the (meth)acrylamide compound, based on the total weight of the composition, may be 0.7 to 2 by weight. In some embodiments, the ratio of the content of the release agent to the content of the (meth)acrylamide compound, based on the total weight of the composition, may be 0.9 to 1.5 or 1 to 1.3 by weight.

Within the above range, the flexural strength of the composition may be increased while maintaining its flowability, thereby improving the moldability and mechanical properties of the composition.

### Epoxy Compound

The epoxy compound may be used to form a base resin or a binder resin that provides thermosetting properties of the resin composition. The epoxy compound may be cross-linked or cured to form an electronic device sealant including an epoxy resin.

The epoxy compound may include a biphenyl epoxy compound and a biphenyl-aralkyl epoxy compound.

The biphenyl epoxy compound may refer to a compound in which epoxy groups are bonded to both terminals at the para positions of a biphenyl group via ether linkages. For example, the biphenyl epoxy compound may be included to enhance the flow properties of the resin composition and improve its moldability.

According to exemplary embodiments, the biphenyl epoxy compound may be represented by Formula 2 below.

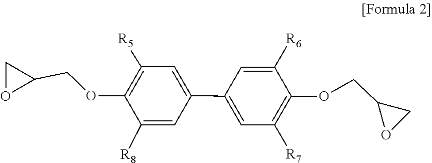

In Formula 2 above, R₅, R₆, R₇ and R₈ may each independently be hydrogen or an alkyl group having 1 to 5 carbon atoms.

In one embodiment, in Formula 2, R₅, R₆, R₇ and R₈ may each be a methyl group.

The biphenyl-aralkyl epoxy compound may refer to an epoxy compound in which alkylene groups are respectively bonded to both terminals at the para positions of the biphenyl group.

According to exemplary embodiments, the biphenyl-aralkyl epoxy compound may be represented by Formula 3 below.

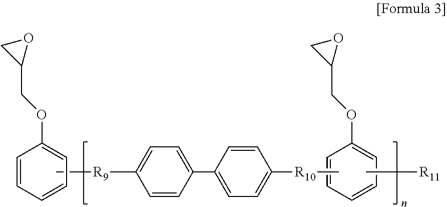

In Formula 3 above, R₉ and R₁₀ may be each an alkylene group having 1 to 5 carbon atoms, and R₁₁ may be hydrogen or an alkyl group having 1 to 5 carbon atoms.

In addition, n is an integer of 1 to 50, 1 to 30, 1 to 20, or 1 to 10.

In one embodiment, R₉ and R₁₀ may be each a methylene group (—CH₂—), and R₁₁ may be hydrogen.

According to exemplary embodiments, a weight ratio of the biphenyl-based epoxy compound to the biphenyl-aralkyl epoxy compound may be greater than 1 and 8 or less. According to some embodiments, the weight ratio of the biphenyl-based epoxy compound to the biphenyl-aralkyl epoxy compound may be 1.4 to 4.5, 1.5 to 4, or 2 to 4.

If the weight ratio is 1 or less, the flow length of the resin composition may be reduced, and as a result, an electronic device sealant having a uniform thickness and desired heat dissipation characteristics may not be formed.

If the weight ratio exceeds 8, a sufficient glass transition temperature of the composition may not be ensured. Accordingly, sufficient heat resistance may not be provided in a high-temperature environment generated in the semiconductor package.

The epoxy compound may be included in an amount of 1 wt % to 15 wt %, 1 wt % to 10 wt %, or 3 wt % to 7 wt % based on the total weight of the resin composition (for example, based on the solid content). Within the above range, a sufficient degree of curing of the resin composition may be ensured, while appropriate flowability and molding characteristics may be maintained.

In one embodiment, a bisphenol epoxy compound (for example, bisphenol Ftype resin) may not be included as the epoxy compound. In this case, a sufficient increase in flow length through the inclusion of the biphenyl epoxy compound may be readily implemented.

### Inorganic Filler

The resin composition may include an inorganic filler. The inorganic filler may enable effective implementation of heat dissipation characteristics in the semiconductor package through the sealant.

For example, the inorganic filler may include fused silica, crystalline silica, calcium carbonate, magnesium carbonate, alumina, magnesia, clay, talc, calcium silicate, titanium oxide, antimony oxide, glass fiber, etc. These may be used alone or in combination of two or more thereof.

The inorganic filler may include alumina particles in consideration of the heat dissipation characteristics. Alumina has a thermal conductivity of 25 to 30 W/m·K and may easily increase the thermal conductivity of the composition. The alumina particles may be a mixture of two or more types of alumina particles having different median particle diameters (e.g., D50).

The alumina particles may include a mixture of small-sized alumina particles having a D50 of 0.1 μm to 1.5 μm and large-sized alumina particles having a D50 of 1 μm to 5 μm. The D50 of the large-sized alumina particles may be greater than that of the small-sized alumina particles.

The inorganic filler may be included in the largest proportion in the resin composition to enhance the heat dissipation effect. For example, the content of the inorganic filler may be 70 wt % to 95 wt %, 80 wt % to 95 wt %, or 87 wt % to 93 wt % based on the solid content of the resin composition.

### Additive

The resin composition may optionally include an additive in consideration of molding characteristics, adhesion characteristics and the like.

The additive may include a curing agent as a component that enhances the hardness of the sealant by cross-linking with the epoxy compound through an epoxy ring-opening reaction.

According to exemplary embodiments, the curing agent may include a resin having a hydroxyl group, and may include a phenolic resin or novolac resin.

For example, the curing agent may include a novolac-type phenol resin, a multifunctional phenol resin, a xylok-type phenol resin, a cresol novolac-type phenol resin, a naphthol-type phenol resin, a terpene-type phenol resin, a dicyclopentadiene-based phenol resin, a novolac-type phenol resin synthesized from bisphenol A and resol, etc. These may be used alone or in combination of two or more thereof.

In one embodiment, the curing agent may include a repeating unit represented by Formula 4 below.

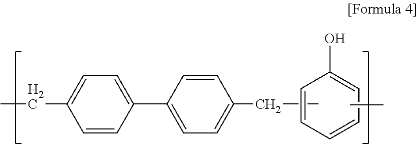

In some embodiments, the curing agent may further include an acid anhydride such as maleic anhydride and phthalic anhydride, and an aromatic amine such as metaphenylenediamine, diaminodiphenylmethane, diaminodiphenylsulfone, etc.

The curing agent may be included in an amount of 1 wt % to 15 wt %, 1 wt % to 10 wt %, or 3 wt % to 8 wt % based on the solid content of the resin composition. Within the above range, sufficient cross-linking properties with the epoxy resin may be ensured, while appropriate flowability and molding characteristics may be maintained.

In one embodiment, the additive may include a coupling agent. For example, the coupling agent may improve the interfacial compatibility between the resin component and the inorganic filler.

The coupling agent may include a silane coupling agent. For example, the coupling agent may include an epoxy silane compound, an amino silane compound, an alkyl silane compound, etc.

In one embodiment, the additive may include a coloring agent for imparting color to the sealant. For example, the coloring agent may include carbon black, etc.

The content of the additive may be appropriately adjusted within a range that does not inhibit functions of the above-described epoxy compound, inorganic filler, (meth)acrylamide compound, and release agent.

For example, a content of the additive may be 0.01 wt % to 2 wt %, 0.05 wt % to 1.5wt %, or 0.1 wt % to 1 wt % based on the solid content of the resin composition.

### Electronic Device

Figure is a schematic cross-sectional view illustrating a semiconductor package in which the resin composition for encapsulating an electronic device according to exemplary embodiments is used. For example, the electronic device may include a semiconductor package.

Referring to FIGURE, the electronic device may include a circuit board 100 and a semiconductor chip 130, and may further include a sealant 150 that fills between the semiconductor chip 130 and the circuit board 100 and bonds them together.

The circuit board 100 may include, for example, a rigid printed circuit board (rigid PCB), a main board, an interposer and the like. Internal lines 110 may be included within the circuit board 100.

The semiconductor chip 130 may be mounted on the circuit board 100 through surface mount technology (SMT). The semiconductor chip 130 may include an AP chip, a logic device, a memory device and the like.

The semiconductor chip 130 may be electrically connected to the internal lines of the circuit board 100 through a conductive intermediary structure 120. The conductive intermediary structure may include the solder, bump, ball grid array (BGA) and the like.

The sealant 150 is formed using the resin composition according to exemplary embodiments, fills a space between the semiconductor chip 130 and the circuit board 100, and may bond the semiconductor chip 130 and the circuit board 100 to each other. For example, the sealant may be formed by curing and molding the resin composition through injection molding, casting molding, etc.

Hereinafter, embodiments of the present invention will be further described with reference to specific experimental examples. However, the following examples and comparative examples included in the experimental examples are only given for illustrating the present invention and those skilled in the art will obviously understand that various alterations and modifications are possible within the scope and spirit of the present invention. Such alterations and modifications are duly included in the appended claims.

### Examples and Comparative Examples

Raw materials were ground and mixed for 5 minutes using a super mixer according to the compositions shown in Tables 1 and 2 below, and then the mixture was melt-kneaded at a temperature of 100° C. in a co-rotating twin-screw extruder having a cylinder inner diameter of 65 mm at a screw rotation speed of 60 to 200 RPM to prepare a molten-kneaded resin composition. Thereafter, a pulverized epoxy resin composition was prepared through cooling and pulverizing processes. The contents of each component were expressed in units of wt % based on the total weight of the composition.

TABLE 1

| | Example | | | | | | | | |
|---|---|---|---|---|---|---|---|---|---|
| | 1 | 2 | 3 | 4 | 5 | 6 | 7 | 8 | 9 |
| A-1 | 3.094 | 3.094 | 3.094 | 3.181 | 2.78 | 3.094 | 3.171 | 2.769 | 2.769 |
| A-2 | 1.326 | 1.326 | 1.326 | 1.363 | 1.191 | 1.326 | 1.359 | 1.187 | 1.187 |
| B-1 | 0.27 | 0.27 | 0.27 | 0.27 | 0.27 | 0.27 | 0.05 | 1.2 | 1.2 |
| C-1 | 0.3 | — | — | 0.05 | 1.2 | — | 0.3 | 0.3 | — |
| C-2 | — | 0.3 | — | — | — | — | — | — | — |
| C-3 | — | — | 0.3 | — | — | — | — | — | — |
| C-4 | — | — | — | — | — | 0.3 | — | — | — |
| C-5 | — | — | — | — | — | — | — | — | 0.3 |
| D | 90 | 90 | 90 | 90 | 90 | 90 | 90 | 90 | 90 |
| E | 4.285 | 4.285 | 4.285 | 4.406 | 3.85 | 4.285 | 4.391 | 3.835 | 3.835 |
| F | 0.155 | 0.155 | 0.155 | 0.16 | 0.139 | 0.155 | 0.159 | 0.139 | 0.139 |
| G | 0.27 | 0.27 | 0.27 | 0.27 | 0.27 | 0.27 | 0.27 | 0.27 | 0.27 |
| H | 0.3 | 0.3 | 0.3 | 0.3 | 0.3 | 0.3 | 0.3 | 0.3 | 0.3 |
| Sum | 100 | 100 | 100 | 100 | 100 | 100 | 100 | 100 | 100 |

TABLE 2

| | Comparative Example | | | | | | |
|---|---|---|---|---|---|---|---|
| | 1 | 2 | 3 | 4 | 5 | 6 | 7 |
| A-1 | 3.188 | 3.188 | 2.696 | 2.696 | 2.696 | 3.188 | 2.696 |
| A-2 | 1.366 | 1.366 | 1.797 | 1.797 | 1.797 | 1.366 | 1.797 |
| B-1 | — | — | 0.27 | 0.27 | — | — | — |
| B-2 | — | — | — | — | 0.27 | — | 0.27 |
| C-1 | — | — | — | — | — | 0.3 | 0.3 |
| C-6 | 0.3 | — | — | 0.3 | 0.3 | — | — |
| C-7 | — | 0.3 | 0.3 | — | — | — | — |
| D | 90 | 90 | 90 | 90 | 90 | 90 | 90 |
| E | 4.416 | 4.416 | 4.209 | 4.209 | 4.209 | 4.416 | 4.209 |
| F | 0.16 | 0.16 | 0.158 | 0.158 | 0.158 | 0.16 | 0.158 |
| G | 0.27 | 0.27 | 0.27 | 0.27 | 0.27 | 0.27 | 0.27 |
| H | 0.3 | 0.3 | 0.3 | 0.3 | 0.3 | 0.3 | 0.3 |
| Sum | 100 | 100 | 100 | 100 | 100 | 100 | 100 |

(A) Epoxy COMPOUND
A-1: Biphenyl epoxy compound (YX-4000H, Mitsubishi Chemical, having the structure of Formula 2-1)

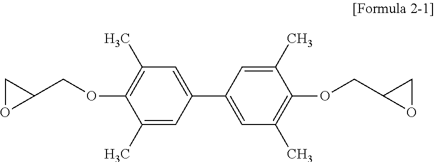 [SMILES: Cc1cc(-c2cc(C)c(OCC3CO3)c(C)c2)cc(C)c1OCC1CO1]

A-2: Biphenyl-aralkyl epoxy compound (NC3000, Nippon Kayaku, having the structure of Formula 3-1)

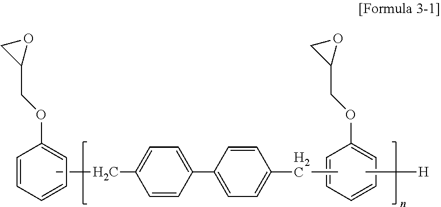

(B) Silane compound
B-1: N-(3-(trimethoxysilyl)propyl)methacrylamide
B-2:3-(amino)propyltrimethoxysilane
(C) Release agent
C-1: Lico Wax E (average acid value: 17.5 mgKOH/g, Montan acid ester wax, Clariant)
C-2: Lico Wax KPS (average acid value: 30 mgKOH/g, Montan ester wax, Clariant)
C-3: Lico Wax S (average acid value: 143.5 mgKOH/g, Montan ester wax, Clariant)
C-4: 1105A (average acid value: 60 mgKOH/g, polyolefin wax, Mitsui)
C-5: Stearic acid (average acid value: 197 mgKOH/g)
C-6: Lico Wax C (average acid value: 8 mgKOH/g or less, N,N-bis-stearyl ethylenediamine amide wax, Clariant)
C-7: Lico Wax OP (average acid value: 12 mgKOH/g, Montan acid ester wax, Clariant)
(D) Inorganic filler: Alumina particles (DAW03, Denka Korea, D50: 3 μm)
(E) Curing agent: Biphenyl aralkyl-type compound (MEH-7851SS, Meiwa, containing repeating units of Formula 4)
(F) Catalyst: 2P4MZHZ-PW, Shikoku
(G) Coupling agent: N-phenyl-γ-aminopropyltrimethoxysilane (Y9669, Momentive)
(H) Colorant: Carbon black (MA-600, Mitsubishi)

### Experimental Example

An experiment was conducted according to the following method, and the measurement and evaluation results are shown in Table 3 below.

### (1) Evaluation of Spiral Flow (Flowability Test)

Using a spiral flow evaluation mold fabricated based on the EMMI-1-66 standard, the flow length of the resin compositions of the examples and comparative examples was measured for 120 seconds using a transfer molding press at a molding temperature of 175° C. and a pressure of 70 kgf/cm². The measured flow length was evaluated as good (acceptable) when it was 45 inches or more, and as poor (defective) when it was less than 45 inches.

### (2) Measurement of Flexural Strength

Using a universal test machine (UTM), the flexural strength of the resin compositions of the examples and comparative examples was measured using the three-point bending method at 25°° C. The measured flexural strength was evaluated as good when it was 110 MPa or more, and as poor when it was less than 110 MPa.

TABLE 3

| | Flowability (inch) | | Flexural strength (MPa) | |
|---|---|---|---|---|
| Example 1 | 55 | Good | 134 | Good |
| Example 2 | 59 | Good | 134 | Good |
| Example 3 | 70 | Good | 130 | Good |
| Example 4 | 50 | Good | 136 | Good |
| Example 5 | 70 | Good | 123 | Good |
| Example 6 | 56 | Good | 131 | Good |
| Example 7 | 59 | Good | 121 | Good |
| Example 8 | 51 | Good | 130 | Good |
| Example 9 | 73 | Good | 110 | Good |
| Comparative | 38 | Poor | 94 | Poor |
| Example 1 | | | | |
| Comparative | 49 | Good | 93 | Poor |
| Example 2 | | | | |
| Comparative | 41 | Poor | 138 | Good |
| Example 3 | | | | |
| Comparative | 30 | Poor | 140 | Good |
| Example 4 | | | | |
| Comparative | 36 | Poor | 105 | Poor |
| Example 5 | | | | |
| Comparative | 55 | Good | 98 | Poor |
| Example 6 | | | | |
| Comparative | 56 | Good | 109 | Poor |
| Example 7 | | | | |

Referring to Table 1, the compositions of the examples included a (meth) acrylamide compound containing an alkoxysilyl group and a wax having an average acid value of 15 mgKOH/g to 200 mgKOH/g.

Referring to Table 3, the compositions of the examples exhibited high flexural strength and increased flow length, thereby improving the flowability of the compositions of the examples.

On the other hand, the compositions of the comparative examples exhibited reduced flowability or low flexural strength, thereby resulting in deterioration of mechanical properties.

The contents described above are merely examples of applying the principles of the present disclosure, and other configurations may be further included without departing from the scope of the present disclosure.

What is claimed is:

1. A resin composition for encapsulating an electronic device, comprising:
an epoxy compound;
an inorganic filler;
a (meth) acrylamide compound including an alkoxysilyl group; and
a release agent comprising a wax having an average acid value of 15 mgKOH/g to 200 mgKOH/g.

2. The resin composition of claim 1, wherein the alkoxysilyl group comprises a trialkoxysilyl group.

3. The resin composition of claim 1, wherein the (meth) acrylamide compound is represented by Formula 1 below: 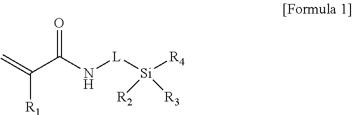
wherein R¹ is hydrogen or a methyl group, R² to R⁴ are each independently an alkoxy group having 1 to 5 carbon atoms, and L is an alkylene group having 1 to 10 carbon atoms.

4. The resin composition of claim 1, wherein the (meth)acrylamide compound comprises N-(3-(trimethoxysilyl)propyl)methacrylamide.

5. The resin composition of claim 1, wherein a content of the (meth)acrylamide compound is 0.05% by weight to 1.5% by weight based on a total weight of the composition.

6. The resin composition of claim 1, wherein the wax has an average acid value of 17 mgKOH/g to 150 mgKOH/g.

7. The resin composition of claim 1, wherein the wax comprises at least one selected from the group consisting of an ester wax, a paraffin wax, an amide wax, and an olefin wax.

8. The resin composition of claim 7, wherein the ester wax comprises an ester wax derived from a carboxylic acid having an alkyl group with 20 to 50 carbon atoms.

9. The resin composition of claim 1, wherein a content of the release agent is 0.05% by weight to 1.5% by weight based on the total weight of the composition.

10. The resin composition of claim 1, wherein a ratio of the content of the release agent to the content of the (meth)acrylamide compound, based on the total weight of the composition, is 0.7 to 2 by weight.

11. The resin composition of claim 1, wherein the epoxy compound comprises a biphenyl-based epoxy compound and a biphenyl-aralkyl-based epoxy compound.

12. The resin composition of claim 11, wherein the biphenyl-based epoxy compound is represented by Formula 2 below: 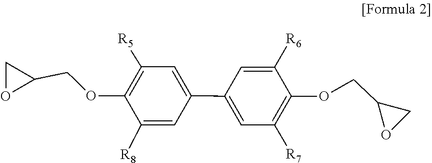
wherein R₅, R₆, R₇ and R₈ are each independently hydrogen or an alkyl group having 1 to 5 carbon atoms.

13. The resin composition of claim 11, wherein the biphenyl-aralkyl epoxy compound is represented by Formula 3 below: 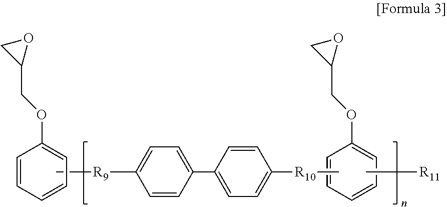
wherein R₉ and R₁₀ are each an alkylene group having 1 to 5 carbon atoms, R₁₁ is hydrogen or an alkyl group having 1 to 5 carbon atoms, and n is an integer of 1 to 10.

14. The resin composition of claim 11, wherein a weight ratio of the biphenyl-based epoxy compound to the biphenyl-aralkyl epoxy compound in the epoxy compound is greater than 1 and 8 or less.

15. The resin composition of claim 1, further comprising an additive which comprises at least one selected from the group consisting of a catalyst, a coupling agent, a colorant, and a curing agent.

16. An electronic device comprising a sealant formed of the resin composition of claim 1.

17. The electronic device according to claim 16, further comprising a circuit board and a semiconductor chip mounted on the circuit board,
wherein the sealant fills a space between the circuit board and the semiconductor chip.
